(19) United States
(12) Patent Application Publication
(10) Pub. No.: US 2025/0327178 A1
(43) Pub. Date: Oct. 23, 2025

(54) ATOMIC LAYER DEPOSITION METHODS AND ASSOCIATED METHODS FOR DEPOSITING A LAYER ON A SUBSTRATE

(71) Applicant: ASM IP Holding B.V., Almere (NL)

(72) Inventor: Jereld Lee Winkler, Gilbert, AZ (US)

(21) Appl. No.: 19/182,785

(22) Filed: Apr. 18, 2025

Related U.S. Application Data
(60) Provisional application No. 63/637,688, filed on Apr. 23, 2024.

(51) Int. Cl. C23C 16/455; C23C 16/52

(52) U.S. Cl. CPC C23C 16/45527; C23C 16/52

(57) ABSTRACT

Atomic layer deposition methods, methods for depositing a layer on a substrate, and associated atomic layer deposition apparatus are disclosed. The methods disclosed include pulsing a reactant gas into a reactor assembly, holding the reactant gas within the reactor assembly for a time period, and purging the reactant gas from the reactor assembly.

### CROSS-REFERENCE TO RELATED APPLICATIONS

This application is a nonprovisional of, and claims priority to and the benefit of, U.S. Provisional Patent Application No. 63/637,688, filed Apr. 23, 2024 and entitled “ATOMIC LAYER DEPOSITION METHODS AND ASSOCIATED METHODS FOR DEPOSITING A LAYER ON A SUBSTRATE,” which is hereby incorporated by reference herein.

### FIELD

The present disclosure relates generally to the field of semiconductor processing methods and to the field of device and integrated circuit manufacture. More particularly the present disclosure generally relates atomic layer deposition methods as well associated methods for depositing a layer on a substrate.

### BACKGROUND

Atomic Layer Deposition (ALD) is a method for growing highly uniform thin layers on a substrate. In a time-divided ALD reactant gas valve, the substrate is placed into reaction space free of impurities and at least two different volatile precursors (reactant gases) are supplied in the vapor phase alternately and repetitively into the reaction space. The layer growth is based on self-limiting surface reactions that take place on the surface of the substrate to form a solid-state layer of atoms or molecules. The reactants are supplied to the reactor assembly of the ALD apparatus in sufficiently high doses for the surface to be practically saturated during each injection cycle. Therefore, ALD methods are highly self-regulating, being not dependent on the concentration of the starting materials. Therefore, it is possible to achieve extremely high layer uniformity and thickness accuracy of a single atomic or molecular layer. Reactants (precursors, co-reactants, and the like) can contribute to the growing layer and/or serve other functions, such as stripping ligands from an adsorbed species of a precursor to facilitate reaction or adsorption of subsequent reactants.

ALD methods can be used for growing both elemental and compound thin films. ALD methods can involve alternate two or more reactants repeated in cycles, and different cycles can have different numbers of reactants. Pure ALD reactions tend to produce less than a monolayer per cycle, although variants of ALD may deposit more than a monolayer per cycle.

Depositing a film using ALD methods can be a slow process due to its step-wise (layer-by-layer) nature. At least two gas reactant pulses are alternated to form one layer of the desired material, and the reactant pulses are kept separated from each other for preventing uncontrolled growth of the film and contamination of the ALD reactor. After each pulse, the gaseous reaction products of the thin-layer growth process as well as the excess reactants in vapor phase are removed from the reaction space. This can be achieved by pumping down the reaction space, by purging the reaction space with an inactive (e.g., inert) gas flow between successive reactant pulses, or both. Purging is widely employed on production scale because of its efficiency and its capability of forming an effective diffusion barrier between the successive pulses. Regularly, the inactive gas purging is also used as a carrier gas during reactant pulses, diluting the reactant vapor before it is fed into the reaction space.

Sufficient substrate exposure and good purging of the reaction space are desirable for a successful ALD processes. That is, the pulses should be intense enough for the substrate to be practically saturated (in the flattened portion of the asymptotic saturation curve) and purging should be efficient enough to remove practically all precursor residues and undesired reaction products from the reactor. However, certain reactants can exhibit inherently slow reaction kinetics which can require extended reactant pulse times and as a result an inefficient utilization of the precursor. Thus, there remains a continuing need for improved atomic layer deposition methods.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to atomic layer deposition methods, ALD apparatus, and associated methods for depositing a layer on a substrate disposed within a reactor assembly.

In accordance with examples of the disclosure, a method of performing atomic layer deposition (ALD) is provided. The method includes pulsing a first reactant gas into a reactor assembly. In such methods pulsing includes supplying the first reactant gas to a first reactant gas line, supplying a first inactive gas to a first inactive gas line at a first flow rate, and feeding the first reactant gas and the first inactive gas to the reactor assembly through a first feed line. The method includes holding the first reactant gas within the reactor assembly. In such methods holding includes supplying the first inactive gas to the first inactive gas line and feeding the first inactive gas to the reactor assembly. The method includes purging the first reactant gas from the reactor assembly. In such methods purging includes supplying the first inactive gas to the first inactive gas line, supplying a second inactive gas to a second inactive gas line at a second flow rate that is higher than the first flow rate, and feeding the first inactive gas and the second inactive gas to the reactor assembly through the first feed line.

In some embodiments, the method of performing atomic layer deposition (ALD) includes continuously supplying the first inactive gas to the reactor assembly.

In some embodiments, the method of performing atomic layer deposition (ALD) includes controlling supply of the first reactant gas to the first feed line employing a first valve and controlling supply of the second inactive gas to the first feed line employing a second valve, wherein the first valve and the second valve are two-state valves.

In some embodiments, the method of performing atomic layer deposition (ALD) includes continuously exhausting the reactor assembly by means of a vacuum source in fluid communication with the reactor assembly by an exhaust line and an active non-zero flow restrictor disposed on the exhaust line between the reactor assembly and the vacuum source.

In some embodiments, the method of performing atomic layer deposition (ALD) includes maintaining a substantially constant pressure within the first feed line. In some embodiments, maintaining the substantially constant pressure includes creating a pressure control signal from a pressure sensor disposed upstream of the reactor assembly, and varying conductance of the exhaust line by communicating the pressure control signal to the active non-zero flow restrictor, wherein the active non-zero flow restrictor alters a degree of flow restriction in response to the pressure control signal.

In some embodiments, the method of performing atomic layer deposition (ALD) includes pulsing a second reactant into the reactor assembly, holding the second reactant within the reactor assembly, and purging the second reactant from the reactor assembly. In some embodiments, the first inactive gas is supplied at the first flow rate while pulsing the second reactant, holding the second reactant, and purging the second reactant, and wherein the second inactive gas is supplied at the second flow rate greater than the first flow rate while purging the second reactant.

In accordance with examples of the disclosure a method for depositing a layer on a substrate disposed within a reactor assembly is provided. The method includes performing an atomic layer deposition process including a plurality of repeated deposition cycles. In such methods each deposition cycle includes performing a first half cycle, the first half cycle including supplying a first reactant gas to the reactor assembly, holding the first reactant gas within the reactor assembly, and purging the first reactant gas from the reactor assembly. In such methods each deposition cycle includes performing a second half cycle, the second half cycle including supplying a second reactant gas to the reactor assembly and purging the second reactant gas from the reactor assembly. In such methods, a first inactive gas is supplied at a first flow rate while performing the first half cycle and the second half cycle, and a second inactive gas is supplied at second flow rate greater than the first flow rate while performing the purging steps. In some embodiments, performing the second half cycle also includes holding the second reactant gas within the reactor assembly.

In some embodiments, the method of depositing a layer on a substrate includes controlling supply of the first reactant gas to a first feed line employing a first valve and controlling supply of the second inactive gas to the first feed line employing a second valve, wherein the first valve and the second valve are two-state valves.

In some embodiments, the method of depositing a layer on a substrate includes continuously exhausting the reactor assembly by means of a vacuum source in fluid communication with the reactor assembly by an exhaust line and an active non-zero flow restrictor disposed on the exhaust line between the reactor assembly and the vacuum source.

In some embodiments, the method of depositing a layer on a substrate includes maintaining a substantially constant pressure within the first feed line. In some embodiments, maintaining the substantially constant pressure includes creating a pressure control signal from a pressure sensor disposed upstream of the reactor assembly, and varying conductance of the exhaust line by communicating the pressure control signal to the active non-zero flow restrictor, wherein the active non-zero flow restrictor alters a degree of flow restriction in response to the pressure control signal.

In accordance with examples of the disclosure an atomic layer deposition method is provided. The method includes pulsing a first reactant gas into a reactor assembly. In such methods the pulsing includes supplying a first inactive gas to a first inactive gas line at a first flow rate, opening a first valve thereby initiating flow of the first reactant gas to a first reactant gas line, closing a second valve thereby terminating flow of a second inactive gas to a second inactive gas line, and feeding the first reactant gas and the first inactive gas to the reactor assembly through a first feed line. The method also includes holding the first reactant gas within the reactor assembly. In such methods holding includes supplying the first inactive gas to the first inactive gas line, closing the first valve thereby terminating flow of the first reactant gas to the first reactant gas line, and feeding the first inactive gas to the reactor assembly. The method also includes purging the reactor assembly. In such methods the purging includes supplying the first inactive gas to the first inactive gas line, opening the second valve thereby initiating flow of the second inactive gas to the second inactive gas line at a second flow rate that is higher than the first flow rate, and feeding the first inactive gas and the second inactive gas to the reactor assembly through the first feed line.

In some embodiments, the atomic layer deposition method includes continuously exhausting the reactor assembly by means of a vacuum source in fluid communication with the reactor assembly by an exhaust line and an active non-zero flow restrictor disposed on the exhaust line between the reactor assembly and the vacuum source.

In some embodiments, the atomic layer deposition method includes maintaining a substantially constant pressure within the first feed line. In some embodiments, maintaining the substantially constant pressure includes creating a pressure control signal from a pressure sensor disposed upstream of the reactor assembly, and varying conductance of the exhaust line by communicating the pressure control signal to the active non-zero flow restrictor, wherein the active non-zero flow restrictor alters a degree of flow restriction in response to the pressure control signal.

In some embodiments, the atomic layer deposition method includes pulsing a second reactant into the reactor assembly, holding the second reactant within the reactor assembly, and purging the second reactant from the reactor assembly.

In some embodiments, the first inactive gas is supplied at the first flow rate while pulsing the second reactant, holding the second reactant, and purging the second reactant, and wherein the second inactive gas is supplied at second flow rate greater than the first flow rate while purging the second reactant.

In some embodiments, the first inactive gas forms a diffusion barrier, the diffusion barrier preventing back diffusion of the first reactant gas.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates exemplary gas flows commonly employed during a half-cycle of an atomic layer deposition process.

FIG. 2 illustrates exemplary gas flows employed during a half-cycle of an atomic layer deposition process in accordance with one or more embodiments of the disclosure.

FIG. 3 illustrates a schematic diagram of an atomic layer deposition apparatus in accordance with one or more embodiments of the disclosure.

FIG. 4 illustrates an atomic layer deposition process in accordance with one or more embodiments of the disclosure.

FIG. 5 illustrates an additional atomic layer deposition process in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. The substrate can include various topologies, such as gaps, including recesses, lines, trenches, or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly, to this, it will be understood the term “under,” “underlying,” or “below” will be construed to be relative concepts.

Commonly employed atomic layer deposition (ALD) methods can include sequentially and alternatingly supplying reactant gases (i.e., precursors and/or co-reactants) and inactive purge gases into a reactor assembly by performing one or more ALD deposition cycle. In such methods, each ALD deposition cycle includes a pulsing step (for introducing a reactant gas into the reactor assembly) followed by a purging step (to remove excess reactant gas and any reactant by-products from the reactor assembly).

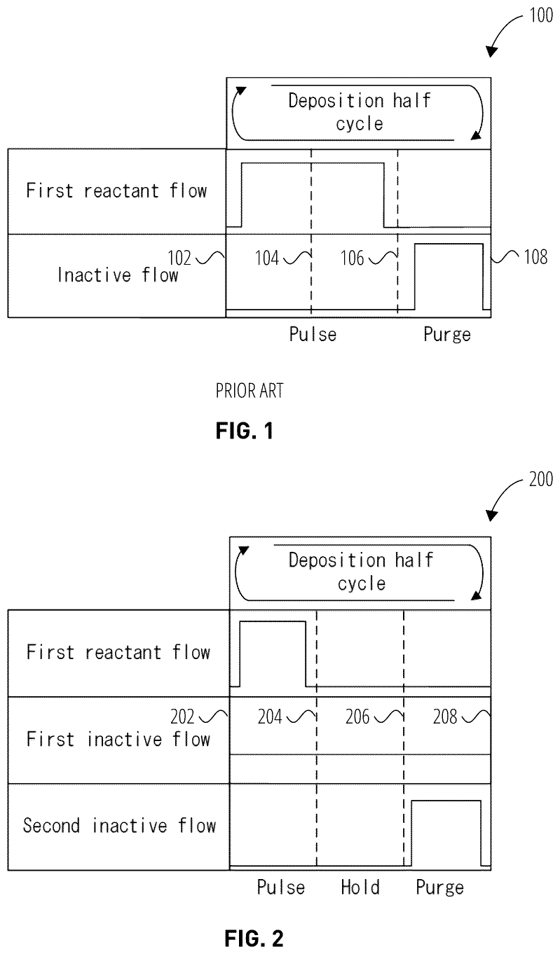

To illustrate the embodiments of the present disclosure, the gas flows of a first half-cycle 100 commonly employed in ALD methods is illustrated in FIG. 1 and exemplary gas flows of second half-cycle 200 of the ALD methods of the present disclosure is illustrated as a comparison in FIG. 2. Both FIG. 1 and FIG. 2 illustrate half-cycle gas flows, i.e., a single sequence of pulsing and purging, whereas a full deposition cycle can include multiple half-cycles. In both FIG. 1 and FIG. 2 the horizontal axis represents the time parameter but does not necessarily represent the actual time length of individual steps, and the vertical axis represents an ON-state or OFF-state for reactant gas flow and inactive gas flow, wherein a raised level on the vertical axis of each parameter represents an ON-state. However, the vertical axis of each line does not necessarily represent the actual quantity of the associated parameter, whereas a bottom level of each line on the vertical axis represents an OFF-state, i.e., zero reactant flow/inactive gas flow.

Turning not to the figures, FIG. 1 illustrates exemplary first half-cycle 100 of a commonly employed ALD methods. In such an example, the first reactant is supplied to the reactor assembly for the time period between 102 and 106 (the pulsing period), and the inactive gas is supplied to the reactor assembly during the time period between 106 and 108 (the purging period). In particular examples, the first reactant is a reactant which exhibits slow reaction kinetics and/or low sticking coefficient. As a result, the pulsing period for the first reactant has an extended time period over that commonly found with reactants with faster reaction kinetics and/or higher sticking coefficients. The extended pulsing period for such “slow” reactants can be needed to ensure sufficient time for the full saturation of the substrate surface and/or the completion of reactions between an absorbed species on the substrate and the incoming first reactant. However, sufficient concentration of the first reactant can introduced into the reactor assembly at an early point in the pulsing period (e.g., at time 104) and the additional pulsing period (between 104 and 106) can be required to ensure saturation/completion of reactions. The additional pulsing period of the first reactant can have a number of negative effects, including, but not limited to, an inefficient utilization of the first reactant, an increase in parasitic deposition, and degradation in the lifetime of the ALD apparatus.

In comparison, FIG. 2 illustrates a second half-cycle 200 of the ALD methods of the present disclosure. In such an example, the first reactant gas is supplied to the reactor assembly for the time period between 202 and 204 (the pulsing period). In addition, a first inactive gas is supplied to the reactor assembly continuously throughout the second half-cycle 200 at a first flow rate, and a second inactive gas is supplied to the reactor assembly, at a second flow rate greater than the first flow rate, for the time period between 206 and 208 (the purging period). The time period between the pulsing step and the purging step (i.e., between 204 and 206) is referred to the as the holding step. In the holding step the first reactant gas and second inactive gas flows are zero and only the first inactive gas is supplied to the reactor assembly at a relative low flow rate compared with the second inactive gas flow employed during the purging step. In such an example, the first reactant gas is again a reactant which exhibits slow reaction kinetics and/or low sticking coefficient. However, when comparing first half-cycle 100 with second half-cycle 200 it is clear that the pulsing period of the methods of the present disclosure (e.g., 202 to 204) is less than the pulsing period of the commonly employed methods (e.g., 102 to 106). In the second half-cycle 200 of the present disclosure, sufficient concentration of the first reactant gas is supplied to the reactor assembly during the shorter pulsing period (202 to 204). However, to allow for adequate time for complete saturation/reactions the holding period (204 to 206) retains the first reactant gas within the reactor assembly. Therefore, second half-cycle 200 supplies a lower concentration of the first reactant gas to the reactor assembly (compared with first half-cycle 100) while still maintaining complete saturation/reactions as a result of the holding step thereby improving utilization of the first reactant gas. In addition, during the holding period, a low flow rate of the first inactive gas is maintained which does not significantly impact the holding period but does ensure continuous flow of an inactive gas through the reactor assembly during the entirety of the second half-cycle 200. A reduction in the concentration of the first reactant gas supplied to the reactor assembly along with continued inactive gas flow throughout the second half-cycle 200 along with continuous exhausting of the reactor assembly (as described below) can improve first reactant gas utilization, prevent parasitic deposition within the reactor assembly, extend reactor assembly component lifetime (e.g., feed lines, exhaust lines, pumps, and the like), and prevent back diffusion of reactant gases.

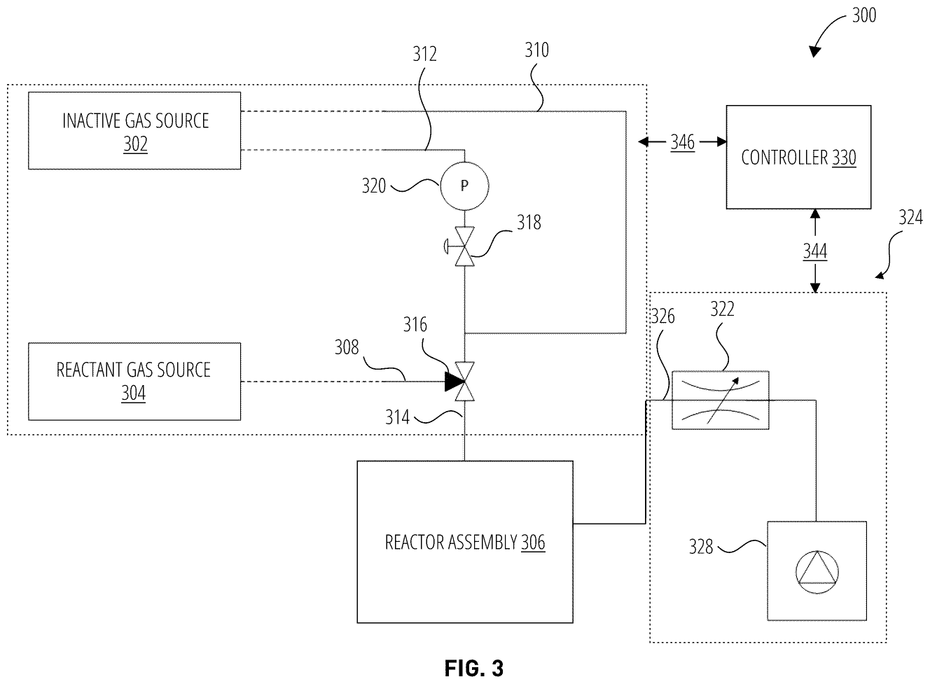

FIG. 3 is a schematic diagram of an ALD apparatus 300 in accordance with embodiments of the disclosure. ALD apparatus 300 can be utilized to perform the ALD methods of the present disclosure.

A reactant gas source 304 is configured to supply a first reactant gas (e.g., vaporized precursor and/or reactant/co-reactant vapor) to the first reactant gas line 308. The reactant gases can comprise a vaporizable material capable of reacting with a substrate surface or a previously reactant left on the substrate surface. The reactants may be naturally solids, liquids, or gases under standard conditions, and accordingly the reactant gas source 304 can include a vaporizer.

A first valve 316 is configured to turn ON or OFF to control the supply of the first reactant gas from the first reactant gas line 308 to the first feed line 314. The first valve 316 can be any suitable type of valve, including, e.g., solenoid-type valves, pneumatic valves, piezoelectric valves, etc. In some embodiments, the first valve 316 is a two-state valve (e.g., including only ON or OFF states) sometimes also referred to a binary valve. As illustrated in FIG. 3, the first valve 316 can comprise a three-way valve which operates as both a two-state valve for controlling flow of the first reactant gas to the first feed line 314, while also continuously allowing flow (and mixing) of the first inactive gas and the second inactive gas, as described in greater detail below. In a particular example, the two-state valve portion of the first valve 316 can comprise a high speed diaphragm valve or a high speed pneumatic valve which operates as two-state valve for rapidly switching the flow of the first reactant gas ON or OFF, where the two-state valve portion of first valve 316 is ON when pulsing first reactant gas to the reactor assembly, as described in detail below.

In accordance with examples of the disclosure, ALD apparatus 300 includes an inactive gas source 302 configured to supply first inactive gas to the first inactive gas line 310 and a second inactive gas to the second inactive gas line 312. The first inactive gas and the second inactive gas are both gases that do not react with reactant gas(es) or the substrate upon which a layer is to be deposited. The first and second inactive gases also serve to prevent reactions between the substances of the different reactant groups, for example by providing a diffusion barrier in the feed line to the reactor assembly between reactant phases. Any suitable type of inactive gases may be used in the embodiments disclosed herein, including, for example, inert gases, such as nitrogen gas, and noble gases, such as argon, for example. The first and second inactive gases may also be inherently reactive gases, such as hydrogen gas serving to prevent undesirable reactions, e.g., oxidization reactions, from occurring on the substrate surface, depending upon relative reactivity with the other reactants. In some embodiments, the first inactive gas and the second inactive gas can both have the same gas composition. In particular examples, both the first inactive gas and the second inactive gas are an inert gas, such as N₂, or Ar, for example.

The first inactive gas is continuously supplied to first inactive gas line 310 (and subsequently to the first feed line 314 and reactor assembly 306). The supply of the second inactive gas to the second inactive gas line 312 (and subsequently to first feed line 314 and reactor assembly 306) is controlled by a second valve 318 configured to turn ON or OFF to control the supply of the second inactive gas from the second inactive gas line 312 to the first feed line 314. The second valve 318 can be any suitable type of valve, including, e.g., solenoid-type valves, pneumatic valves, piezoelectric valves, etc. In some embodiments, the second valve 318 is a two-state valve (e.g., including only ON or OFF states) sometimes also referred to a binary valve. As illustrated in FIG. 3, the second valve 318 can comprise, for example, a high-speed diaphragm valve which operates as two-state valve for rapidly switching the flow of the second inactive gas ON or OFF, where the second valve 318 is ON when purging the reactor assembly 306, as described in detail below.

In accordance with examples of the disclosure, flow control of the first inactive gas and the second inactive gas to the first feed line 314 (and the reactor assembly 306) is achieved without the use of mass flow controllers on either inactive gas lines (310, 312). Mass flow controllers (and the like) commonly introduce a delay in the flow of gases especially when alternating between a high flow regime and a low flow regime, as employed in the pulse, hold, purge methods of the present disclosure.

The process gases (reactants and inactives) sequentially supplied to the first feed line 314 are introducing into the reactor assembly 306 for performing atomic layer deposition on a substrate disposed within the reactor assembly 306. In various arrangements, the reactor assembly 306 can include a reaction chamber comprising a substrate support (not shown) configured to support a substrate (not shown).

The ALD apparatus 300 of FIG. 3 includes an exhaust system 324. In accordance with examples of the disclosure, the exhaust system 324 can be configured for continuously exhausting the reactor assembly 306. Exhaust system 324 includes a vacuum source 328 (e.g., a vacuum pump) in fluid communication with the reactor assembly by means of the exhaust line 326. The flow of exhausted gas and/or the level of vacuum (i.e., pressure) in the reactor assembly 306 can be controlled with a flow restrictor 322 disposed on the exhaust line 326 between the reactor assembly 306 and the vacuum source 328. In particular examples, the flow restrictor 322 is an active flow restrictor, where the term “active” in this example can refer to a flow restrictor device in which the degree of restriction in the device can be controlled. Further in particular examples, the flow restrictor 322 is non-zero flow restrictor, where the term “non-zero” in this examples can refer to a flow restrictor which does not fully prevent exhaust gas flow, i.e., the non-zero flow restrictor continuously permits at least some processes gas to be exhausted from the reactor assembly 306. In some embodiments, the flow restrictor 322 is an active non-zero flow restrictor, i.e., a device having controllable restriction without fully prevent gas flow (e.g., exhaust gas flow). In such embodiments, the flow restrictor 322 can comprise a throttle valve.

In accordance with examples of the disclosure, the ALD apparatus 300 of FIG. 3 can be configured to perform isobaric ALD processes. In such examples, one or deposition cycles of the ALD methods provided can be performed at constant pressure. In such exemplary ALD methods, the pressure within at least the reactor assembly 306 and/or the first feed line 314 is maintained at constant value, or a substantially constant value, where “substantially” in this example can refer to a percentage change in the pressure during ALD processes of less than 0.5%, less than 1%, less than 2%, less than 5%, less than 10%, or less than 20%, or between 0.5% and 20%.

In accordance with examples of the disclosure, isobaric operation of ALD apparatus 300 can include monitoring the pressure in the ALD apparatus 300. As a non-limiting example, a pressure sensor 320 can be disposed upstream of the reactor assembly 306 for monitoring pressure, e.g., in the reactor assembly 306 and/or the first feed line 314. In a particular examples, the pressure sensor 320 is disposed on the second inactive gas line 312 between the first valve 316 and second valve 318, as illustrated in FIG. 3. In some embodiments, the pressure sensor 320 is linked (e.g., via exemplary links 344 and 346 which can be wired and/or wireless) to a controller 330 to enable communication/control between at least the pressure sensor 320, the flow restrictor 322, and the controller 330.

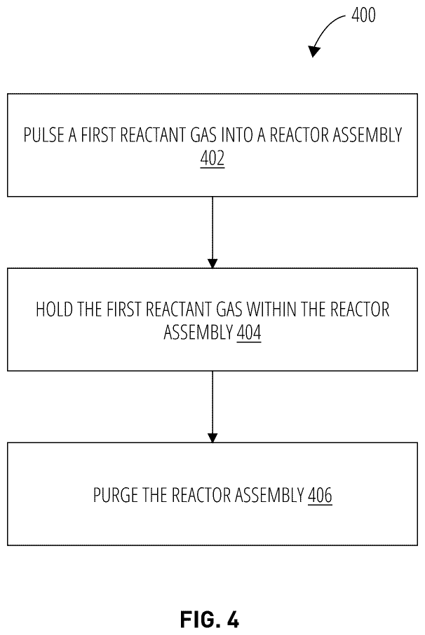

An exemplary method of performing atomic layer deposition in accordance with the present disclosure is illustrated in FIG. 4 and is described in detail below with reference also to the ALD apparatus 300 of FIG. 3. In brief, FIG. 4 illustrates an ALD method 400 (e.g., a deposition half-cycle) which comprises, pulsing a first reactant gas into the reactor assembly 306 (step 402), holding the first reactant gas within the reactor assembly 306 (step 404), and purging the reactor assembly 306 (step 406).

In accordance with examples of the disclosure, ALD method 400 includes pulsing a first reactant gas into the reactor assembly 306 (step 402). In such examples, the pulsing step (402) can comprise, supplying the first reactant gas to a first reactant gas line 308. For example, the first reactant gas is supplied from reactant gas source 304. In such examples, the pulsing step (step 402) also comprises, supplying a first inactive gas to a first inactive gas line 310 at a first flow rate. In such examples, the pulsing step (step 402) can also comprise, feeding the first reactant gas and the first inactive gas to the reactor assembly 306 through the first feed line 314.

In accordance with examples of the disclosure, ALD method 400 includes holding the first reactant gas within the reactor assembly 306 (step 404). In such examples, the holding step (step 404) can comprise, supplying the first inactive gas to the first inactive gas line 310. In such examples, the hold step (step 404) also comprises, feeding the first inactive gas to the reactor assembly 306.

In accordance with examples of the disclosure, ALD method 400 includes purging the first reactant gas from the reactor assembly 306 (step 406). In such examples, the purging step (step 406) can comprise, supplying the first inactive gas to the first inactive gas line 310 and supplying a second inactive gas to a second inactive gas line 312. In particular examples, the second inactive gas is supplied at a second flow rate that is higher than the first flow rate (i.e., the flow rate of the first inactive gas). Further in such examples, the purging step (406) can comprise, feeding the first inactive gas and the second inactive gas to the reactor assembly 306 through the first feed line 314.

As described above, the first inactive gas is continuously supplied to the reactor assembly 306. The continuous flow of the first inactive gas (i.e., the low flow inactive gas as illustrated in second half-cycle 200 of FIG. 2) along with continuous exhausting of the reactor assembly 306 (as described below) can prevent, or reduce, “dead-spaces” within the ALD apparatus 300, i.e., regions within the ALD apparatus 300 where process gases (reactants, precursors, co-reactants, and the like) can reside for extended periods of time. Such residual process gases within the ALD apparatus 300 can result in unwanted parasitic deposition and a degradation of both deposition quality and apparatus (and associated components) lifetime.

In accordance with examples of the disclosure, the flow control of the first reactant gas (from reactant gas source 304) can comprise, controlling the supply of the first reactant gas to the first feed line 314 employing a first valve 316 (as described above). The flow control of the second inactive gas (from the inactive gas source 302) can comprise, controlling the supply of the second inactive gas to the first feed line 314 employing a second valve (as described above). In such examples, the first valve 316 and the second valve 318 can comprise two-state valves (i.e., ON or OFF binary valves). Controlling process gases with two-state valves can remove the need for slow mass flow controllers, thereby increasing the gas switching speeds and efficiency of the ALD apparatus 300.

In accordance with further examples of the disclosure, the ALD method 400 (FIG. 4) can be performed as an isobaric process, in which the pressure within the reactor assembly 306 and/or the first feed line 314 is maintained at a substantially constant pressure. In such examples, maintaining the substantially constant pressure can comprise, creating a pressure control signal from a pressure sensor 320 disposed upstream of the reactor assembly 306, and varying the conductance of the exhaust line 326 by communicating the pressure control signal (via controller 330 and link 344, link 346) to the flow restrictor 322 (e.g., active non-zero flow restrictor, such as a throttle valve, and the like). In such examples, the flow restrictor 322 alters a degree of flow restriction (and hence conductance in the exhaust line 326) in response to the pressure control signal.

The present disclosure also provides additional atomic layer deposition (ALD) deposition methods which utilize the pulsing, holding, purging, sequences described in detail above. In accordance with such examples of the disclosure (and with continued references to the ALD apparatus 300 of FIG. 3), additional ALD methods provided include, (A) pulsing a first reactant gas into the reactor assembly 306, (B) holding the first reactant gas within the reactor assembly 306, and (C) purging the reactor assembly.

In greater detail and in accordance with examples of the disclosure, pulsing a first reactant gas into the reactor assembly 306 comprises, opening a first valve 316 thereby initiating flow of the first reactant gas to the first reactant gas line 308, closing a second valve 318 thereby terminating flow of the second inactive gas to a second inactive gas line 312 (i.e., stopping the high flow purge gas), and feeding the first reactant gas and the first inactive gas to the reactor assembly 306 through the first feed line 314. In such examples, one or more of the steps can be performed concurrently or least with some degree of temporal overlap.

In accordance with further examples, of the disclosure, holding the first reactant gas within the reactor assembly 306 comprises, supplying the first inactive gas to the first inactive gas line 310, closing the first valve 316 thereby terminating flow of the first reactant gas to the first reactant gas line 308, and feeding the first inactive gas to the reactor assembly 306. Again, in such examples, one or more of the steps can be performed concurrently or least with some degree of temporal overlap.

In accordance with yet further examples of the disclosure, purging the reactor assembly 306 of the first reactant gas comprises, supplying the first inactive gas to the first inactive gas line 310, opening the second valve 318 thereby initiating flow of the second inactive gas to the second inactive gas line 312 at a second flow rate that is higher than the first flow rate (i.e., introducing the high flow purge gas), and feeding the first inactive gas and the second inactive gas to the reactor assembly 306 through the first feed line 314. Again, in such examples, one or more of the steps can be performed concurrently or least with some degree of temporal overlap.

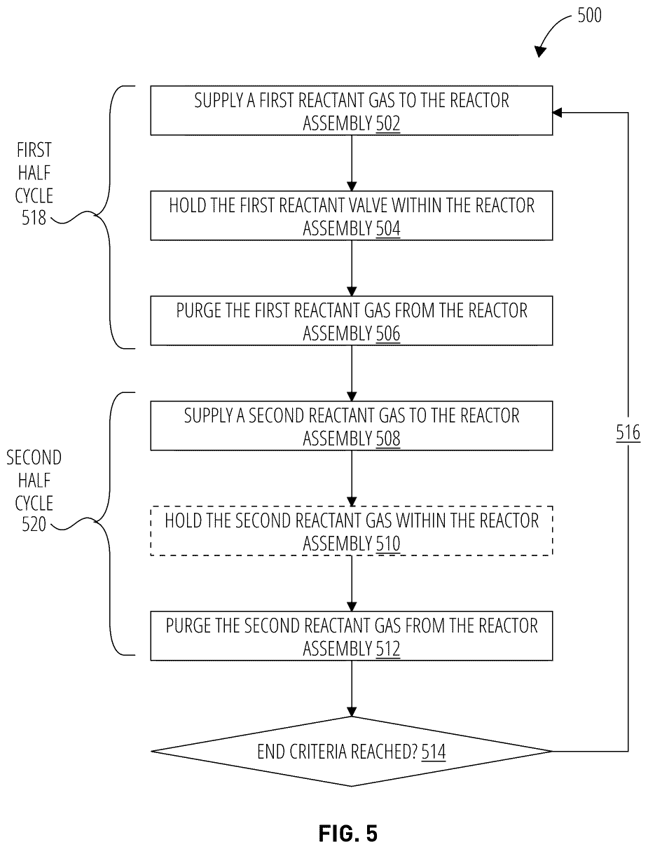

Various embodiments of the present disclosure also provide method for depositing a layer on a substrate disposed within a reactor assembly. As a non-limiting example, FIG. 5 illustrates an exemplary method 500 for depositing a layer. In such examples, the exemplary deposition method 500 comprises, performing an atomic layer deposition process comprising a plurality of repeated deposition cycles. In particular examples, each deposition cycle comprises performing a first half cycle 518 and a second half cycle 520.

In accordance with examples of the disclosure, performing the first half cycle 518 comprises, supplying a first reactant gas to the reactor assembly (step 502), holding the first reactant gas within the reactor assembly (504), and purging the first reactant gas from the reactor assembly (504). The details of the supplying the first reactant (step 502), holding the first reactant (step 504), and purging the first reactant (step 506) have been described in detail above.

In accordance with additional examples of the disclosure performing the second half cycle 520 comprises, supplying a second reactant gas to the reactor assembly (step 510), optionally holding the second reactant gas within the reactor assembly (optional step 510), and purging the second reactant gas from the reactor assembly (step 512). In such examples, the second reactant gas can be sourced from the reactant gas source 304 of ALD apparatus 300 (FIG. 3) and provided to the reactor assembly through the first feed line 314 or alternatively through a separate second feed line (with associated valving and purging, as described above).

In some embodiments, the exemplary method 500 includes, supplying the first inactive gas at a first flow rate while performing the first half cycle 518 and the second half cycle 520, and supplying a second inactive gas at second flow rate greater than the first flow rate while performing the purging steps (step 506 and step 512).

In accordance with examples of the disclosure, each deposition cycle (e.g., first half cycle 518 and second half cycle 520) is repeated (as indicated by deposition cycle loop 516) one or more time until a desired end criterion is reach (decision block 514). In such examples, the end criterion of deposition method 500 can be reached when a desired thickness of a layer is deposited on the substrate or alternatively when a predetermined number of deposition cycles have been performed.

In accordance with examples of the disclosure, the individual half-cycles (518 and 520) of the exemplary method 500 can be performed in any order or sequence, in parallel (or at least partially in parallel), without or without addition process steps, or omitting steps illustrated in FIG. 5. As a non-limiting example, in some deposition processes, the second reactant gas may comprise the “slow” reactant and the first reactant may comprise the “faster reactant”, in which case the holding step (step 504) can be omitted from the first half cycle 518 and the optional holding step (step 510) can be included in the second half cycle 520 to increase the utilization of the second reactant gas. As a further non-limiting example, in some deposition processes, both the first reactant vapor and the second reactant gas can both comprise “slow” reactants, in which case the holding steps (step 504 and optional step 510) can be employed in both the first half cycle 518 and the second half cycle 520.

In accordance with examples of the disclosure, the ALD apparatus 300 in conjunction with the ALD method described above (e.g., methods 400 and 500) allows for rapid inactive gas flow purging. Such rapid modulation of the ALD apparatus 300 from low-flow inactive gas purging to high-flow inactive gas purging is achieved by utilizing the pressure control (as described above) for high flow purge gas (e.g., N₂ or Ar, and the like) in conjunction with the rapid switching of the second valve 318 (such as a pneumatic diaphragm valve, for example) positioned upstream of the first valve 316 (e.g., a pulse valve on a pulsed valve manifold). In accordance with examples of the disclosure, inactive purge gas flow can be set high during the purging step (406) (by the introduction of the second inactive gas from the second inactive gas line 312) and low during the both the pulsing step (402) and holding step (404) by activating or deactivating (ON vs OFF state) of the second valve 318 (e.g., a rapid purge gas pneumatic valve). In particular examples, the continuous supply of the low flow rate first inactive gas can also control the flow restrictor 322 (e.g., a throttle valve) to lower conductance in the exhaust line 326 to maintain pressure and as a result can reduce the pumping speed to the vacuum source in the exhaust system 342, further improve utilization of the reactant gases.

In accordance with examples of the disclosure, the ALD methods provided in the present disclosure include utilizing pressure control and thereby the methods and associated apparatus eliminate overpressure in the first feed line 314 which allows the pressure in the first feed line 314 to be controlled at a substantial constant value (i.e., constant pressure) regardless of state of the second valve 318 (i.e., the rapid high-flow purge valve) or cycle time between the various steps of the ALD methods described above. In addition, the methods provided also increase the chemical utilization rate (e.g., of the first reactant gas) by employing the holding step 404 (FIG. 4) (i.e., when low flow first inactive gas is supplied to the reactor assembly after the pulse step 402.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of performing atomic layer deposition (ALD), method comprising:
pulsing a first reactant gas into a reactor assembly, the pulsing comprising:
supplying the first reactant gas to a first reactant gas line;
supplying a first inactive gas to a first inactive gas line at a first flow rate; and
feeding the first reactant gas and the first inactive gas to the reactor assembly through a first feed line;
holding the first reactant gas within the reactor assembly, the holding comprising:
supplying the first inactive gas to the first inactive gas line; and
feeding the first inactive gas to the reactor assembly;
purging the first reactant gas from the reactor assembly, the purging comprising:
supplying the first inactive gas to the first inactive gas line;
supplying a second inactive gas to a second inactive gas line at a second flow rate that is higher than the first flow rate;
feeding the first inactive gas and the second inactive gas to the reactor assembly through the first feed line.

2. The method of claim 1, further comprising continuously supplying the first inactive gas to the reactor assembly.

3. The method of claim 2, further comprising controlling supply of the first reactant gas to the first feed line employing a first valve, and controlling supply of the second inactive gas to the first feed line employing a second valve, wherein the first valve and the second valve are two-state valves.

4. The method of claim 3, further comprising continuously exhausting the reactor assembly by means of a vacuum source in fluid communication with the reactor assembly by an exhaust line and an active non-zero flow restrictor disposed on the exhaust line between the reactor assembly and the vacuum source.

5. The method of claim 4, further comprising maintaining a substantially constant pressure within the first feed line.

6. The method of claim 5, where maintaining the substantially constant pressure comprises:
creating a pressure control signal from a pressure sensor disposed upstream of the reactor assembly; and
varying conductance of the exhaust line by communicating the pressure control signal to the active non-zero flow restrictor, wherein the active non-zero flow restrictor alters a degree of flow restriction in response to the pressure control signal.

7. The method of claim 1, further comprising pulsing a second reactant into the reactor assembly, holding the second reactant within the reactor assembly, and purging the second reactant from the reactor assembly.

8. The method of claim 7, wherein the first inactive gas is supplied at the first flow rate while pulsing the second reactant, holding the second reactant, and purging the second reactant, and wherein the second inactive gas is supplied at the second flow rate greater than the first flow rate while purging the second reactant.

9. A method for depositing a layer on a substrate disposed within a reactor assembly, the method comprising:
performing an atomic layer deposition process comprising a plurality of repeated deposition cycles, wherein each deposition cycle comprises;
performing a first half cycle comprising:
supplying a first reactant gas to the reactor assembly;
holding the first reactant gas within the reactor assembly;
purging the first reactant gas from the reactor assembly; and
performing a second half cycle comprising:
supplying a second reactant gas to the reactor assembly; and
purging the second reactant gas from the reactor assembly,
wherein a first inactive gas is supplied at a first flow rate while performing the first half cycle and the second half cycle, and a second inactive gas is supplied at second flow rate greater than the first flow rate while performing the purging steps.

10. The method of claim 9, further comprising controlling supply of the first reactant gas to a first feed line employing a first valve, and controlling supply of the second inactive gas to the first feed line employing a second valve, wherein the first valve and the second valve are two-state valves.

11. The method of claim 10, further comprising continuously exhausting the reactor assembly by means of a vacuum source in fluid communication with the reactor assembly by an exhaust line and an active non-zero flow restrictor disposed on the exhaust line between the reactor assembly and the vacuum source.

12. The method of claim 11, further comprising maintaining a substantially constant pressure within the first feed line.

13. The method of claim 12, where maintaining the substantially constant pressure comprises:
creating a pressure control signal from a pressure sensor disposed upstream of the reactor assembly; and
varying conductance of the exhaust line by communicating the pressure control signal to the active non-zero flow restrictor, wherein the active non-zero flow restrictor alters a degree of flow restriction in response to the pressure control signal.

14. The method of claim 9, wherein the performing the second half cycle further comprises, holding the second reactant gas within the reactor assembly.

15. An atomic layer deposition (ALD) method comprising:
pulsing a first reactant gas into a reactor assembly, the pulsing comprising:
supplying a first inactive gas to a first inactive gas line at a first flow rate;
opening a first valve thereby initiating flow of the first reactant gas to a first reactant gas line; and
closing a second valve thereby terminating flow of a second inactive gas to a second inactive gas line; and
feeding the first reactant gas and the first inactive gas to the reactor assembly through a first feed line;
holding the first reactant gas within the reactor assembly, the holding comprising:
supplying the first inactive gas to the first inactive gas line;
closing the first valve thereby terminating flow of the first reactant gas to the first reactant gas line; and
feeding the first inactive gas to the reactor assembly;
purging the reactor assembly, the purging comprising:
supplying the first inactive gas to the first inactive gas line;
opening the second valve thereby initiating flow of the second inactive gas to the second inactive gas line at a second flow rate that is higher than the first flow rate; and
feeding the first inactive gas and the second inactive gas to the reactor assembly through the first feed line.

16. The method of claim 15, further comprising continuously exhausting the reactor assembly by means of a vacuum source in fluid communication with the reactor assembly by an exhaust line and an active non-zero flow restrictor disposed on the exhaust line between the reactor assembly and the vacuum source.

17. The method of claim 16, further comprising maintaining a substantially constant pressure within the first feed line, where maintaining the substantially constant pressure comprises:
creating a pressure control signal from a pressure sensor disposed upstream of the reactor assembly; and
varying conductance of the exhaust line by communicating the pressure control signal to the active non-zero flow restrictor, wherein the active non-zero flow restrictor alters a degree of flow restriction in response to the pressure control signal.

18. The method of claim 17, further comprising pulsing a second reactant into the reactor assembly, holding the second reactant within the reactor assembly, and purging the second reactant from the reactor assembly.

19. The method of claim 18, wherein the first inactive gas is supplied at the first flow rate while pulsing the second reactant, holding the second reactant, and purging the second reactant, and wherein the second inactive gas is supplied at second flow rate greater than the first flow rate while purging the second reactant.

20. The method of claim 19, wherein the first inactive gas forms a diffusion barrier, the diffusion barrier preventing back diffusion of the first reactant gas.
